(19) United States
(12) Patent Application Publication
(10) Pub. No.: US 2024/0295239 A1
(43) Pub. Date: Sep. 5, 2024

(54) HINGE ASSEMBLY AND ELECTRONIC DEVICE

(71) Applicant: VIVO MOBILE COMMUNICATION CO., LTD., Dongguan (CN)

(72) Inventors: Wenhui ZENG, Dongguan (CN); Yu LONG, Dongguan (CN); Yang LIU, Dongguan (CN)

(73) Assignee: VIVO MOBILE COMMUNICATION CO., LTD., Dongguan (CN)

(21) Appl. No.: 18/646,751

(22) Filed: Apr. 25, 2024

Related U.S. Application Data
(63) Continuation of application No. PCT/CN2022/126898, filed on Oct. 24, 2022.

(30) Foreign Application Priority Data
Oct. 27, 2021 (CN) 202111260331.5

(51) Int. Cl. F16C 11/04; H05K 5/02

(52) U.S. Cl. CPC F16C 11/04; H05K 5/0226

(57) ABSTRACT

A hinge assembly and an electronic device are provided. The hinge assembly includes: a base provided with a first fitting portion and a second fitting portion; a first synchronizing shaft; a second synchronizing shaft; a first movable piece; and a second movable piece. A first end of the first synchronizing shaft is able to be movably connected to the first fitting portion. A first end of the second synchronizing shaft is able to be movably connected to the second fitting portion. A first end of the first movable piece is provided with a first gear sleeve. An outer surface of the first gear sleeve is provided with a first gear end. The first gear sleeve is connected to and moves synchronously with the first synchronizing shaft. A first end of the second movable piece is provided with a second gear sleeve.

### CROSS-REFERENCE TO RELATED APPLICATIONS

This application is a continuation of International Application No. PCT/CN2022/126898, filed on Oct. 24, 2022, which claims priority to Chinese Patent Application No. 202111260331.5, filed on Oct. 27, 2021. The entire contents of each of the above-referenced applications are expressly incorporated herein by reference.

### TECHNICAL FIELD

This application pertains to the field of electronic device technologies, and specifically, relates to a hinge assembly and an electronic device.

### BACKGROUND

Currently, there are two types of foldable screen hinges in the market: waterdrop hinges and U-shaped hinges. Key components of a foldable screen hinge mainly include a hinge assembly, a gear synchronization mechanism, a damping mechanism, and the like. The gear synchronization mechanisms mostly have four gears that engage with each other, and the four gears are mounted on four shafts, respectively, and need to be fastened by four circlips, resulting in complex assembly. In addition, there are many intermediate links between gears and swing arms, resulting in poor synchronization and large spatial dimensions.

### SUMMARY

This application is intended to provide a hinge assembly and an electronic device.

This application is implemented as follows.

According to a first aspect, an embodiment of this application provides a hinge assembly. The hinge assembly includes: a base, where the base is provided with a first fitting portion and a second fitting portion; a first synchronizing shaft, where a first end of the first synchronizing shaft is able to be movably connected to the first fitting portion; a second synchronizing shaft, where a first end of the second synchronizing shaft is able to be movably connected to the second fitting portion; a first movable piece, where a first end of the first movable piece is provided with a first gear sleeve, an outer surface of the first gear sleeve is provided with a first gear end, and the first gear sleeve is connected to and moves synchronously with the first synchronizing shaft; and a second movable piece, where a first end of the second movable piece is provided with a second gear sleeve, an outer surface of the second gear sleeve is provided with a second gear end, the second gear sleeve is connected to and moves synchronously with the second synchronizing shaft, and the second gear end engages with the first gear end.

According to a second aspect, an embodiment of this application provides an electronic device. The electronic device includes a flexible screen, a first part, a second part, and the hinge assembly according to any one of the foregoing embodiments. The first part is connected to the first movable piece, the second part is connected to the second movable piece, and the flexible screen covers the first part, the hinge assembly, and the second part.

In the embodiments of this application, the first gear end and the second gear end engage directly or indirectly, implementing left-right synchronization. The first gear end and the first movable piece are designed as one piece, and the second gear end and the second movable piece are designed as one piece, reducing the number of parts. The first movable piece and the second movable piece can directly participate in engaging, shortening a synchronization chain, reducing intermediate links and an assembly tolerance, and achieving better synchronization.

Some of additional aspects and merits of the present application are provided in the following descriptions, and some become apparent from the following descriptions or are learned of through practice of the present application.

### BRIEF DESCRIPTION OF DRAWINGS

FIG. 1 is a partial exploded view of an electronic device according to an embodiment of the present application;

FIG. 2 is a schematic diagram of fitting a hinge assembly, a first part, and a second part together according to an embodiment of the present application;

FIG. 3 is a schematic diagram of a structure of a hinge assembly according to an embodiment of the present application;

FIG. 4 is a view of a section obtained along line A-A in FIG. 2;

FIG. 5 is a schematic diagram of a structure of an electronic device that is in a folded state according to an embodiment of the present application;

FIG. 6 is an exploded view of a hinge assembly according to an embodiment of the present application;

FIG. 7 is a schematic diagram of a partial structure of a hinge assembly according to an embodiment of the present application;

FIG. 8 is a schematic diagram of a structure of a first movable piece of a hinge assembly according to an embodiment of the present application;

FIG. 9 is a schematic enlarged view of region B in FIG. 3;

FIG. 10 is a partial exploded view of an electronic device according to another embodiment of the present application;

FIG. 11 is a schematic diagram of fitting a hinge assembly, a first part, and a second part together according to another embodiment of the present application;

FIG. 12 is a schematic diagram of a structure of a hinge assembly according to another embodiment of the present application;

FIG. 13 is a schematic enlarged view of region C in FIG. 12;

FIG. 14 is a view of a section obtained along line A′-A′ in FIG. 11; and

FIG. 15 is a schematic diagram of a structure of an electronic device that is in a folded state according to another embodiment of the present application.

### DETAILED DESCRIPTION

The following clearly describes the technical solutions in the embodiments of this application with reference to the accompanying drawings in the embodiments of this application. Apparently, the described embodiments are only some rather than all of the embodiments of this application. All other embodiments obtained by a person of ordinary skill in the art based on the embodiments of this application without creative efforts shall fall within the protection scope of this application.

A feature modified by the term “first,” “second,” or the like in the specification and claims of this application can explicitly or implicitly include one or more such features. In the description of the present application, “a plurality of” means two or more unless otherwise specified. In addition, in this specification and claims, “and/or” indicates at least one of the connected objects, and the character “/” generally indicates an “or” relationship between the contextually associated objects.

In the description of the present application, the orientations or positional relationships indicated by the technical terms “center,” “longitudinal,” “transverse,” “length,” “width,” “thickness,” “upper,” “lower,” “front,” “rear,” “left,” “right,” “vertical,” “horizontal,” “top,” “bottom,” “inside,” “outside,” “clockwise,” “counterclockwise,” “axial,” “radial,” “circumferential,” and the like are based on the orientations or positional relationships as shown in the accompanying drawings. These terms are merely for the ease and brevity of description of the present application rather than indicating or implying that the apparatuses or components mentioned must have specific orientations or must be constructed or manipulated according to specific orientations, and therefore shall not be construed as any limitations on the present application.

In the description of the present application, it should be noted that unless otherwise specified and defined explicitly, the terms “mount,” “connect,” “join,” and “attach” should be understood in their general senses. For example, they may refer to a fixed connection, a detachable connection, or an integral connection; a mechanical connection or an electrical connection; and a direct connection, an indirect connection via an intermediate medium, or an internal communication between two elements. A person of ordinary skill in the art can understand specific meanings of these terms in the present application based on specific situations.

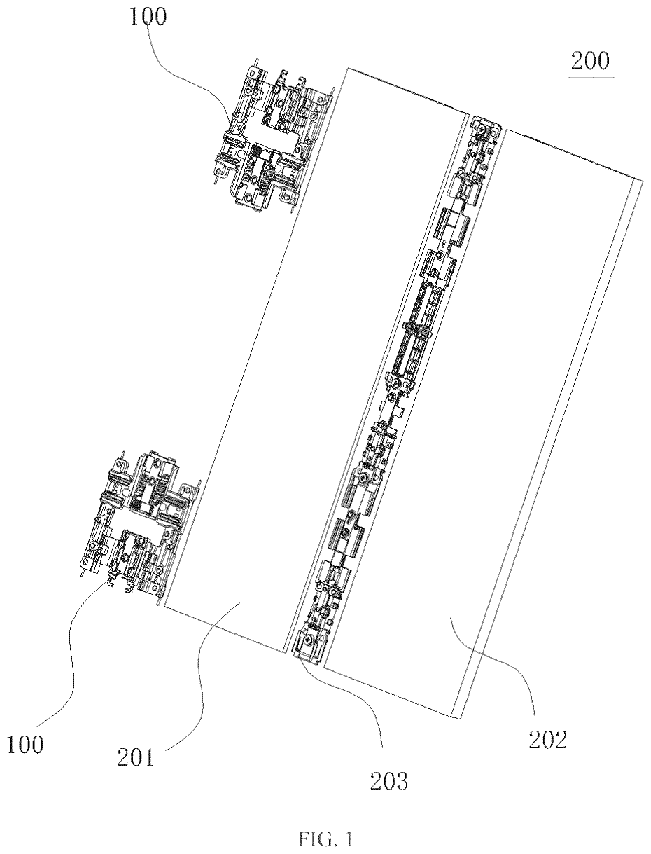

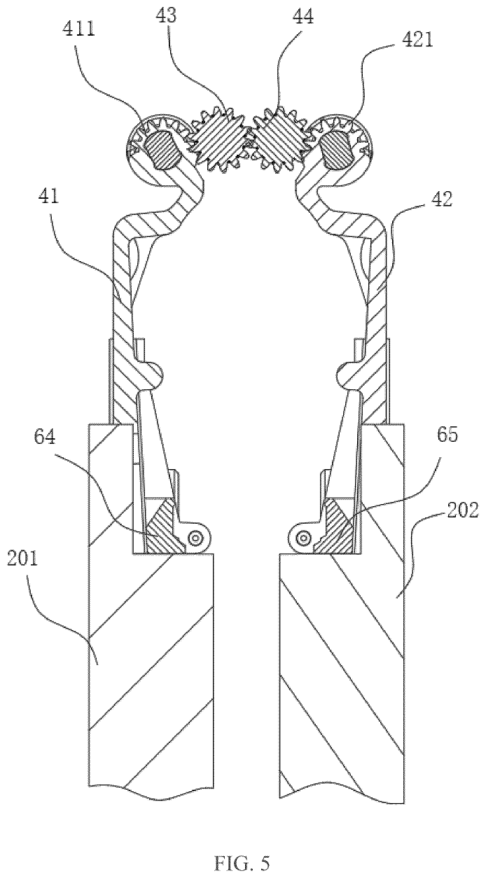

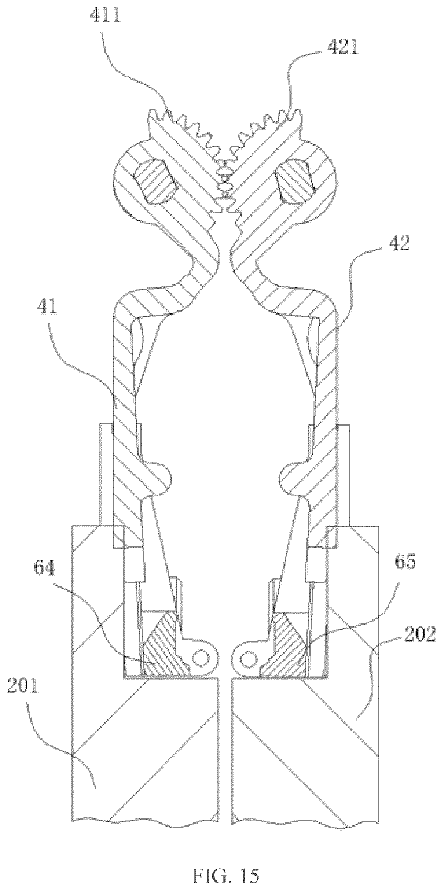

The following describes a hinge assembly 100 according to an embodiment of the present application with reference to FIG. 1 to FIG. 15.

The hinge assembly 100 according to this embodiment of this application includes a base 10, a first synchronizing shaft 20, a second synchronizing shaft 30, a first movable piece 41, and a second movable piece 42.

In some embodiments, the base 10 is provided with a first fitting portion 11 and a second fitting portion 12. A first end of the first synchronizing shaft 20 is able to be movably connected to the first fitting portion 11. A first end of the second synchronizing shaft 30 is able to be movably connected to the second fitting portion 12. A first end of the first movable piece 41 is provided with a first gear sleeve, an outer surface of the first gear sleeve is provided with a first gear end 411, and the first gear sleeve is connected to and moves synchronously with the first synchronizing shaft 20.

A first end of the second movable piece 42 is provided with a second gear sleeve, an outer surface of the second gear sleeve is provided with a second gear end 421, and the second gear sleeve is connected to and moves synchronously with the second synchronizing shaft 30. The second gear end 421 engages with the first gear end 411.

In other words, the hinge assembly 100 according to this embodiment of this application mainly includes the base 10, the first synchronizing shaft 20, the second synchronizing shaft 30, the first movable piece 41, and the second movable piece 42. The hinge assembly 100 according to this embodiment of this application may be used in an electronic device 200. The electronic device 200 includes a first part 201 and a second part 202.

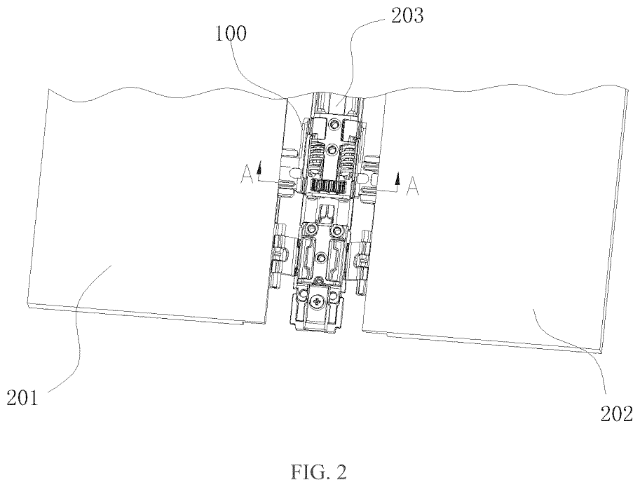

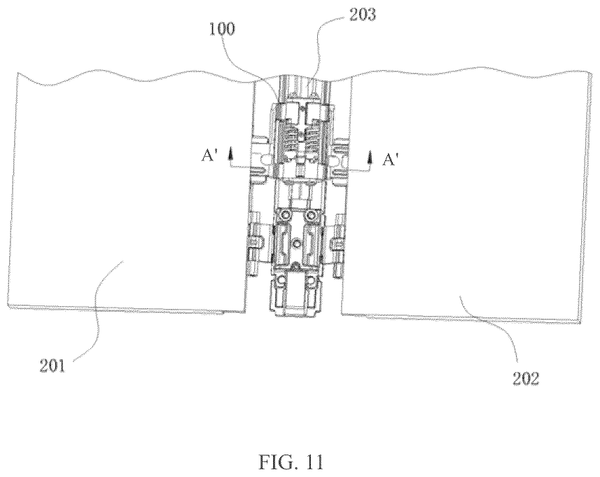

As shown in FIG. 2 and FIG. 11, when the electronic device 200 is divided into a left body and a right body, the first part 201 may be at least a part of the left body, and the second part 202 may be at least a part of the right body.

A middle frame support 203 may be disposed between the left body and the right body. A foldable flexible screen may be disposed on a same side of the left body and the right body. The base 10 may be disposed on the middle frame support 203. The hinge assembly 100 in this application is capable of driving the left body and the right body to move, implementing unfolding and closing of the flexible screen.

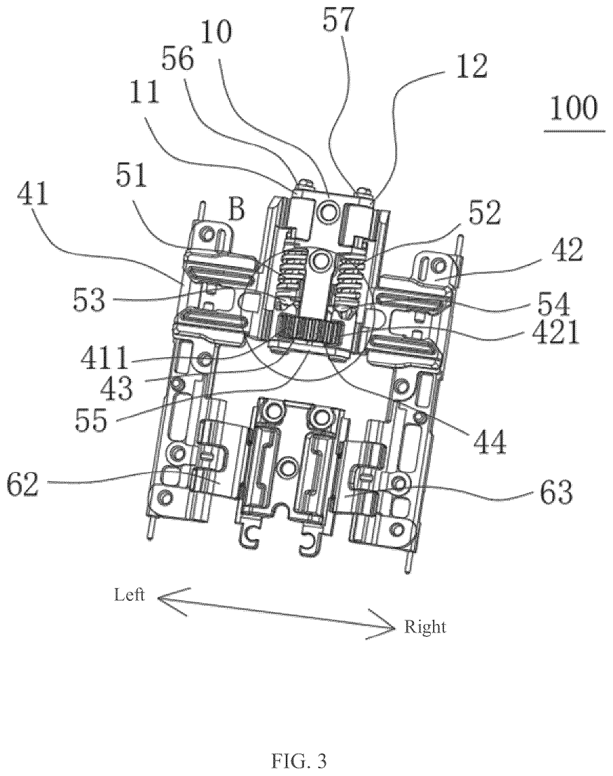

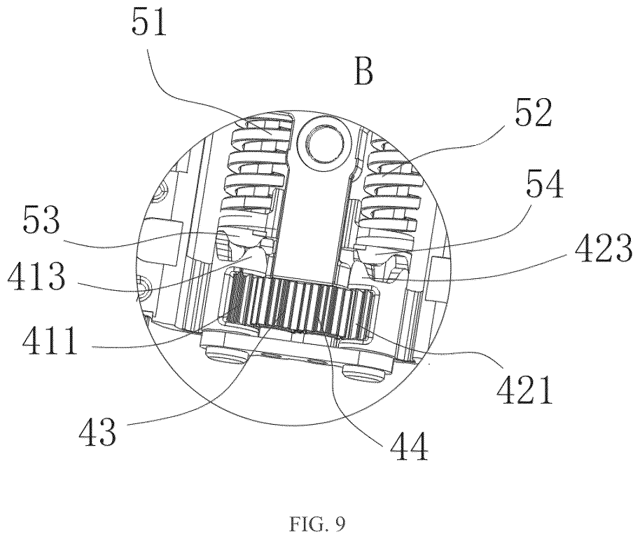

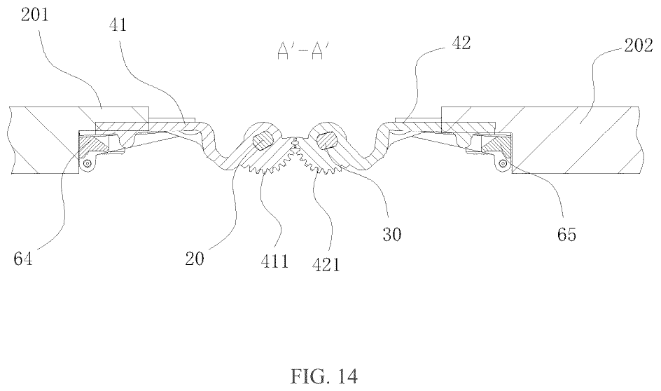

As shown in FIG. 3, FIG. 9, and FIG. 14, the first movable piece 41 may serve as a left synchronizing swing arm, and the second movable piece 42 may serve as a right synchronizing swing arm. The first end of the first movable piece 41 is provided with the first gear sleeve. The outer surface of the first gear sleeve is provided with the first gear end 411.

The first movable piece 41 and the first gear sleeve are designed as one piece. Therefore, there are merits such as a compact structure and high space utilization. Likewise, the first end of the second movable piece 42 is provided with the second gear sleeve. The second movable piece 42 and the second gear sleeve are designed as one piece. Details are not described herein again.

The outer surface of the first gear sleeve is provided with the first gear end 411. The first gear end 411 is connected to the first synchronizing shaft 20, and the two move synchronously. For example, when the first synchronizing shaft 20 rotates, the first gear end 411 also rotates. The outer surface of the second gear sleeve is provided with the second gear end 421. The second gear end 421 is connected to the second synchronizing shaft 30, and the two move synchronously. For example, when the second synchronizing shaft 30 rotates, the second gear end 421 also rotates.

In other words, the first gear end 411 and the second gear end 421 may fit together to form at least a part of a synchronization mechanism. With the synchronization mechanism, the left body and the right body can rotate synchronously. The second gear end 421 and the first gear end 411 may engage directly or indirectly. With the second gear end 421 engaging with the first gear end 411, it can be ensured that the left and right bodies rotate synchronously, avoiding skewness.

The first movable piece 41 moves synchronously with the first synchronizing shaft 20. Therefore, when rotating, the first movable piece 41 can simultaneously drive the first synchronizing shaft 20 and the first gear sleeve on the first movable piece 41 to rotate, thereby driving the first gear end 411 to rotate. With the first movable piece 41 moving synchronously with the first synchronizing shaft 20, the first synchronizing shaft 20 can move relative to the base 10, reducing a force of friction between the first synchronizing shaft 20 and the base 10.

Likewise, the second movable piece 42 moves synchronously with the second synchronizing shaft 30. Therefore, when rotating, the second movable piece 42 can simultaneously drive the second synchronizing shaft 30 and the second gear sleeve on the second movable piece 42 to rotate, thereby driving the second gear end 421 to rotate. Details are not described herein again.

When the hinge assembly 100 is being folded, the first gear end 411 and the second gear end 421 rotate towards each other. When the hinge assembly 100 is being unfolded, the first gear end 411 and the second gear end 421 rotate away from each other.

When the first gear end 411 and the second gear end 421 engage directly, a synchronization chain in this embodiment may be roughly as follows: the first part 201—the first movable piece 41—the first gear sleeve—the first gear end 411—the second gear end 421—the second gear sleeve—the second movable piece 42—the second part 202, that is, the left body—the first movable piece 41—the first gear sleeve—the first gear end 411—the second gear end 421—the second gear sleeve—the second movable piece 42—the right body.

In this embodiment, the first gear end 411 and the second gear end 421 engage directly or indirectly, implementing left-right synchronization. The first gear end 411 and the first movable piece 41 are designed as one piece, and the second gear end 421 and the second movable piece 42 are designed as one piece, reducing the number of parts. The first movable piece and the second movable piece can directly participate in engaging, shortening the synchronization chain, reducing intermediate links and an assembly tolerance, and achieving better synchronization.

According to an embodiment of this application, the hinge assembly 100 further includes a first gear 43 and a second gear 44.

In some embodiments, the first gear 43 is able to be rotatably disposed on the base 10, and the first gear 43 engages with the first gear end 411. The second gear 44 is able to be rotatably disposed on the base 10, and the second gear 44 engages with both the first gear 43 and the second gear end 421.

In other words, the first gear 43 and the second gear 44 are also disposed on the base 10. The first gear 43 and the second gear 44 are located between the first gear end 411 and the second gear end 421. The first gear end 411 engages with the first gear 43, the second gear end 421 engages with the second gear 44, and the first gear 43 engages with the second gear 44. For example, with the first gear 43 and the second gear 44 disposed, the first gear end 411 engages with the second gear end 421 indirectly.

The first gear end 411, the first gear 43, the second gear 44, and the second gear end 421 may fit together to form at least a part of a synchronization mechanism. When the first gear end 411, the first gear 43, the second gear 44, and the second gear end 421 rotate, the first gear end 411, the first gear 43, the second gear 44, and the second gear end 421 engage with each other, ensuring that the left and right bodies rotate synchronously, and avoiding skewness.

It can be learned that a synchronization chain in this embodiment may be roughly as follows: the first part 201—the first movable piece 41—the first gear sleeve—the first gear end 411—the first gear 43—the second gear 44—the second gear end 421—the second gear sleeve—the second movable piece 42—the second part 202, that is, the left body—the first movable piece 41—the first gear sleeve—the first gear end 411—the first gear 43—the second gear 44—the second gear end 421—the second gear sleeve—the second movable piece 42—the right body.

In this embodiment, the first gear end 411, the first gear 43, the second gear 44, and the second gear end 421 engage with each other, expanding an unfolding range of a foldable screen and helping design of large screens while implementing left-right synchronization.

According to an embodiment of this application, the first gear sleeve is provided with a first mounting hole 412, and a second end of the first synchronizing shaft 20 is disposed in the first mounting hole 412. During installation, the first gear sleeve is sleeved on the first synchronizing shaft 20, implementing fitting of the first gear sleeve and the first synchronizing shaft 20.

The second gear sleeve is provided with a second mounting hole 422, and a second end of the second synchronizing shaft 30 is disposed in the second mounting hole 422. During installation, the second gear sleeve is sleeved on the second synchronizing shaft 30, implementing fitting of the second gear sleeve and the second synchronizing shaft 30. Therefore, easy fitting is achieved.

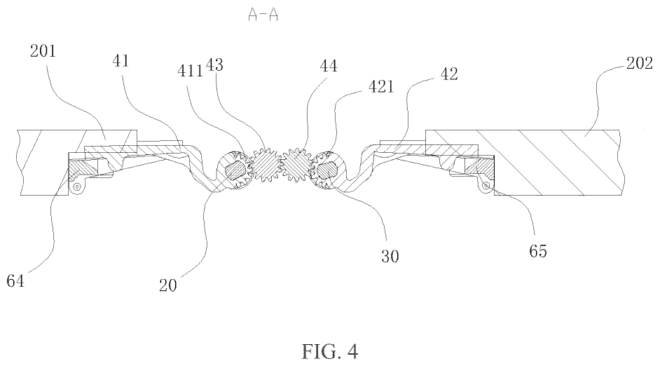

In some implementations of this application, as shown in FIG. 4 and FIG. 14, the first synchronizing shaft 20 is a cylindrical piece, a section of the first synchronizing shaft 20 in an axial direction of the first synchronizing shaft 20 is non-circular, and an inner wall surface of the first mounting hole 412 presses against an outer wall surface of the first synchronizing shaft 20.

The second synchronizing shaft 30 is a cylindrical piece, a section of the second synchronizing shaft 30 in an axial direction of the second synchronizing shaft 30 is non-circular, and an inner wall surface of the second mounting hole 422 presses against an outer wall surface of the second synchronizing shaft 30. Non-circular includes rectangular-like, special-shaped, and the like.

In this embodiment, with the sections of the first synchronizing shaft 20 and the second synchronizing shaft 30 being non-circular, it can be avoided that the first synchronizing shaft 20 slides relative to the inner wall surface of the first mounting hole 412, and the second synchronizing shaft 30 slides relative to the inner wall surface of the second mounting hole 422, further ensuring that the first synchronizing shaft 20 moves synchronously with the first movable piece 41 and that the second synchronizing shaft 30 moves synchronously with the second movable piece 42.

According to an embodiment of this application, the first fitting portion 11 is provided with a first channel, and the first end of the first synchronizing shaft 20 is able to movably fit in the first channel. During installation, the first fitting portion 11 is sleeved on the first synchronizing shaft 20 from the first end of the first synchronizing shaft 20 through the first channel.

The second fitting portion 12 is provided with a second channel, and the first end of the second synchronizing shaft 30 is able to movably fit in the second channel. During installation, the second fitting portion 12 is sleeved on the second synchronizing shaft 30 from the first end of the second synchronizing shaft 30 through the second channel. This has merits such as easy fitting and a stable structure.

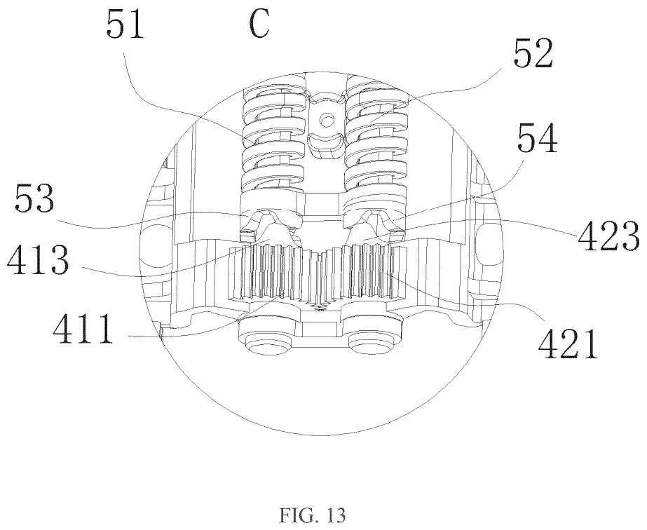

According to an embodiment of this application, as shown in FIG. 3, FIG. 9, and FIG. 13, the hinge assembly 100 further includes a first elastic piece 51 and a second elastic piece 52.

In some embodiments, a first end of the first elastic piece 51 in a telescoping direction of the first elastic piece 51 is connected to the first fitting portion 11, and a second end of the first elastic piece 51 in the telescoping direction of the first elastic piece 51 is connected to the first gear sleeve. When a reaction force of the first elastic piece 51 to the first gear sleeve is larger, it is easier to increase an action force that is required when the first gear end 411 and the first gear 43, or the first gear end 411 and the second gear end 421 continue to engage.

A first end of the second elastic piece 52 in a telescoping direction of the second elastic piece 52 is connected to the second fitting portion 12, and a second end of the second elastic piece 52 in the telescoping direction of the second elastic piece 52 is connected to the second gear sleeve. Likewise, by a degree to which the second elastic piece 52 is stretched or compressed, the second elastic piece 52 can also control an action force that is required when the second gear end 421 and the second gear 44, or the second gear end 421 and the first gear end 411 continue to engage.

In this embodiment, the first elastic piece 51 may fit together with the first fitting portion 11, the base 10, and the like to form at least a part of a first damping mechanism, and the second elastic piece 52 may fit together with the second fitting portion 12, the base 10, and the like to form at least a part of a second damping mechanism. With the first damping mechanism and the second damping mechanism disposed, a sense of damping can be provided during unfolding and closing of the left and right bodies.

In some embodiments, the first elastic piece 51 is a first spring, and the first spring is sleeved on a periphery of the first synchronizing shaft 20. The second elastic piece 52 is a second spring, and the second spring is sleeved on a periphery of the second synchronizing shaft 30. In this embodiment, the adopted first spring and the second spring have not only a merit of being easy to be sleeved on the first synchronizing shaft 20 and the second synchronizing shaft 30 but also merits such as being inexpensive and widely available.

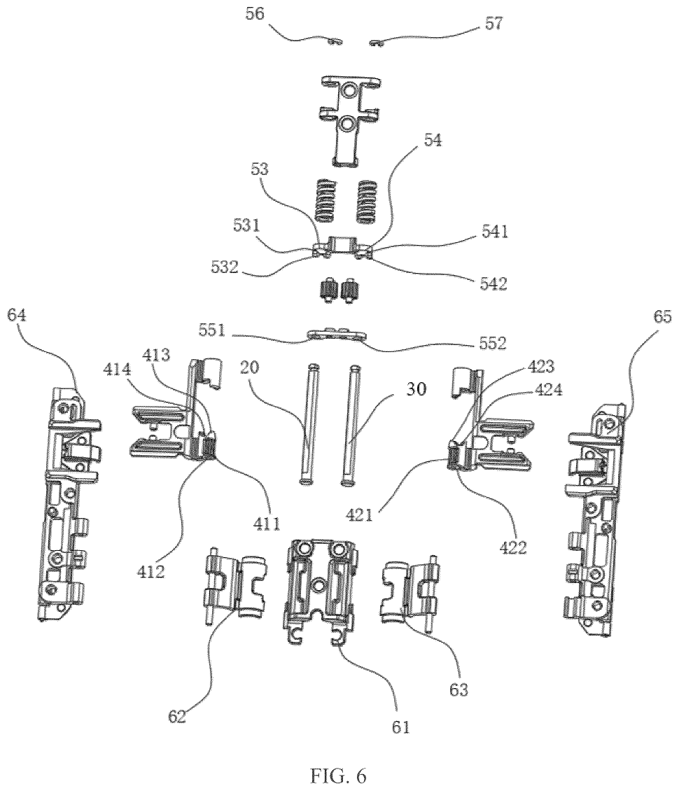

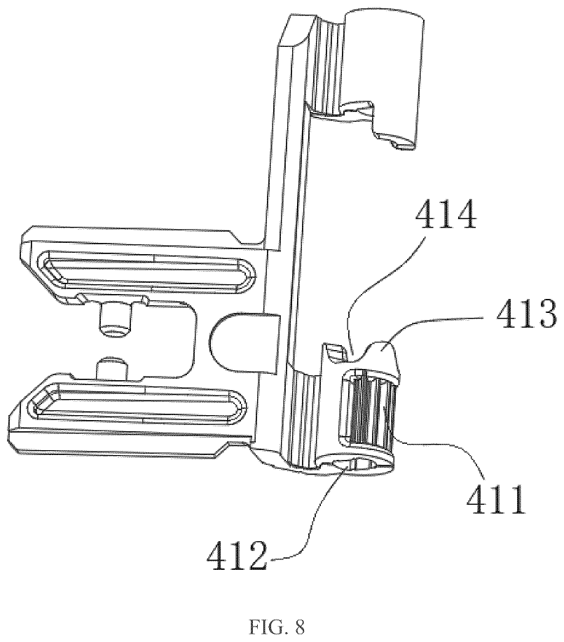

According to an embodiment of this application, as shown in FIG. 3, FIG. 6, and FIG. 8, the first gear sleeve has a first fitting surface that is provided opposite the second end of the first elastic piece 51, the first fitting surface is provided with a plurality of first protruding portions 413 that are spaced apart in a direction in which the first synchronizing shaft 20 rotates, and a first recessed portion 414 is formed between two adjacent first protruding portions 413.

The second gear sleeve has a second fitting surface that is provided opposite the second end of the second elastic piece 52, the second fitting surface is provided with a plurality of second protruding portions 423 that are spaced apart in a direction in which the second synchronizing shaft 30 rotates, and a second recessed portion 424 is formed between two adjacent second protruding portions 423.

The hinge assembly 100 further includes a first cam 53 and a second cam 54.

The first cam 53 is connected to the second end of the first elastic piece 51, the first cam 53 has a third fitting surface facing the first fitting surface, the third fitting surface is provided with a first protrusion 532 and a first recess 531 that are spaced apart in a direction in which the first synchronizing shaft 20 rotates, a shape of the first protrusion 532 corresponds to a shape of the first recessed portion 414, a shape of the first recess 531 corresponds to a shape of the first protruding portion 413, and the first cam 53 may rotate around an axis of the first synchronizing shaft 20 to adjust a preload of the first elastic piece 51 against the first gear sleeve.

The second cam 54 is connected to the second end of the second elastic piece 52, the second cam 54 has a fourth fitting surface facing the second fitting surface, the fourth fitting surface is provided with a second protrusion 542 and a second recess 541 that are spaced apart in a direction in which the second synchronizing shaft 30 rotates, a shape of the second protrusion 542 corresponds to a shape of the second recessed portion 424, a shape of the second recess 541 corresponds to a shape of the second protruding portion 423, and the second cam 54 may rotate around an axis of the second synchronizing shaft 30 to adjust a preload of the second elastic piece 52 against the second gear sleeve.

The base 10 may include a gear support. The first fitting portion 11 and the second fitting portion 12 may be disposed on the gear support. The left synchronizing swing arm, the gear support, the first synchronizing shaft 20, the first elastic piece 51, and the like may fit together to form a first gear mechanism. The gear support may be screwed to the middle frame support 203. The first synchronizing shaft 20 may be fitted in the gear support.

In other words, the first gear sleeve has the first protruding portions 413 and the first recessed portions 414, that is, has a cam shape. The first cam 53 has the first protrusions 532 and the first recesses 531. The first gear sleeve fits together with the first cam 53, implementing interlocking. Likewise, the second gear sleeve also has the second protruding portions 423 and the second recessed portions 424, and the second cam 54 has the second protrusions 542 and the second recesses 541. The second gear sleeve fits together with the second cam 54, also implementing interlocking. With the first gear sleeve, the first cam 53, the second gear sleeve, and the second cam 54 fitting together with each other, the first gear sleeve and the first cam 53 can be interlocked and the second gear sleeve and the second cam 54 can be interlocked when the left and right bodies are in a fully closed state and a fully unfolded state, avoiding reverse movement of the left and right bodies.

When an external force is applied to make the left and right bodies change from a closed state to an unfolded state, ends of the left and right synchronizing swing arms slide in grooves of corresponding guide supports, respectively, and the cam shape part of the first gear sleeve applies pressure to the first cam 53 and slides. As a result, the first elastic piece 51 is compressed. When being compressed, the first elastic piece 51 provides reverse thrust to the first cam 53. Likewise, when being compressed, the second spring piece provides reverse thrust to the second cam 54. For example, a sense of damping is provided during unfolding of the left and right bodies and allows for a hovering state at any angle within the opening and closing range. When being rotated to 180°, the left and right bodies are unfolded. When the left synchronizing swing arm and the first cam 53 interlock and the right synchronizing swing arm and the second cam 54 interlock, the first elastic piece 51 and the second elastic piece 52 return to initial states, respectively. When an external force is applied to make the left and right bodies change from the unfolded state to the closed state, the foregoing process is reversed.

In this embodiment, with the first elastic piece 51, the cam shape of the first gear sleeve, and the first cam 53 fitting with each other, and the second elastic piece 52, the cam shape of the second gear sleeve, and the second cam 54 fitting with each other, the hovering of the left and right bodies during the unfolding and closing process can be achieved.

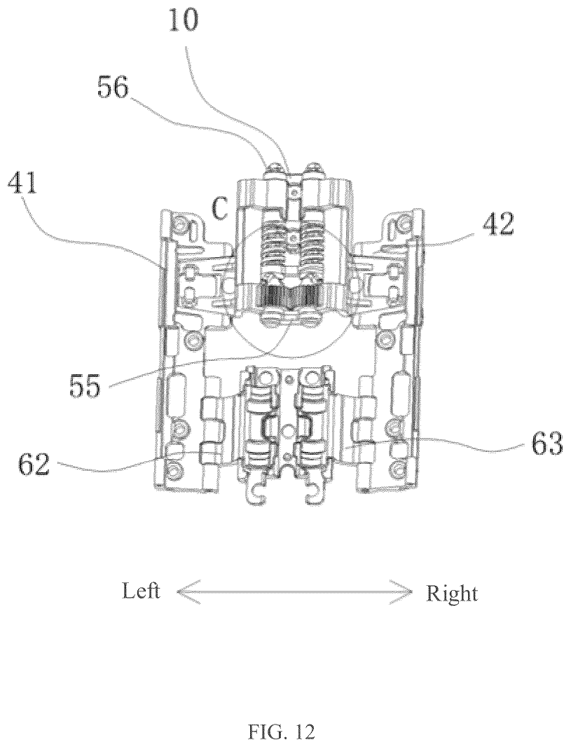

According to an embodiment of this application, as shown in FIG. 3 and FIG. 12, the hinge assembly 100 further includes a position-limiting piece 55. The position-limiting piece 55 is connected to both a second end of the first synchronizing shaft 20 and a second end of the second synchronizing shaft 30, the position-limiting piece 55 is provided with a first positioning hole 551 and a second positioning hole 552, the second end of the first synchronizing shaft 20 passes through the first positioning hole 551, and the second end of the second synchronizing shaft 30 passes through the second positioning hole 552.

During installation, the position-limiting piece 55 may be first installed on the first synchronizing shaft 20 and the second synchronizing shaft 30, limiting relative positions of the first synchronizing shaft 20 and the second synchronizing shaft 30, and further limiting relative positions of the first gear end 411 and the second gear end 421. This facilitates tight engaging of the first gear end 411 and the second gear end 421 or tight engaging of the first gear end 411, the first gear 43, the second gear 44, and the second gear end 421.

According to an embodiment of this application, the second end of the first synchronizing shaft 20 and the second end of the second synchronizing shaft 30 are each provided with a shaft cap, and the hinge assembly 100 further includes a first circlip 56 and a second circlip 57.

The first circlip 56 is connected to the first end of the first synchronizing shaft 20. The second circlip 57 is connected to the first end of the second synchronizing shaft 30.

During fitting, the first gear sleeve, the first cam 53, the first elastic piece 51, and the gear support may be sleeved on the first synchronizing shaft 20 sequentially. The second end of the first synchronizing shaft 20 may then be fastened by the first circlip 56.

The following provides a description by using the first synchronizing shaft 20 as an example.

When this solution is compared with an existing solution in which two ends of a synchronizing shaft both need to be fastened by a circlip, the second end of the first synchronizing shaft 20 in this embodiment is provided with a shaft cap. During fitting, the first gear sleeve and the like are sleeved on the first synchronizing shaft 20 from the first end of the first synchronizing shaft 20. Because the second end of the first synchronizing shaft 20 has a shaft cap structure, and the shaft cap structure can limit a position of the first synchronizing shaft 20, there is no need to additionally install a circlip at the second end of the first synchronizing shaft 20 for fastening. In this way, the first synchronizing shaft 20 in this embodiment needs only one first circlip 56 to limit the position of the first synchronizing shaft 20, providing merits such as a simple structure, easy fitting, and low costs.

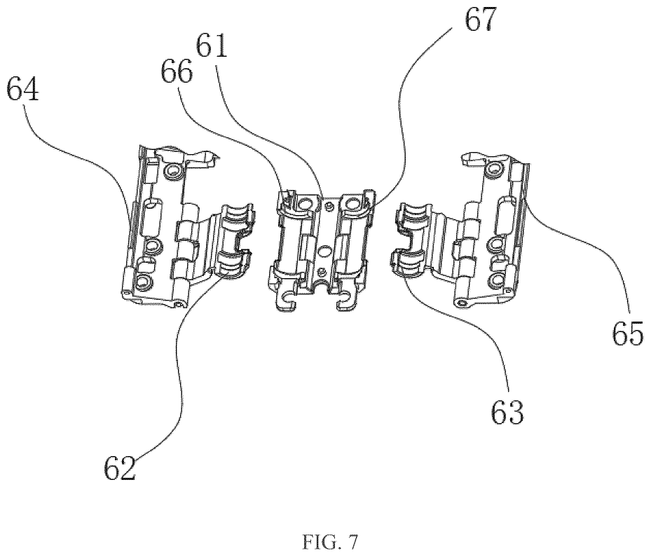

According to an embodiment of this application, as shown in FIG. 6 and FIG. 7, the hinge assembly 100 further includes a guide cover 61, a first swing arm 62, a second swing arm 63, a first guide support 64, and a second guide support 65.

In some embodiments, the guide cover 61 is spaced apart from the base 10, and two ends of a first surface of the guide cover 61 are provided with a first chute 66 and a second chute 67, respectively. A first end of the first swing arm 62 is slidably connected to the first chute 66.

A first end of the second swing arm 63 is slidably connected to the second chute 67. A first end of the first guide support 64 is movably connected to a second end of the first swing arm 62. A first end of the second guide support 65 is movably connected to a second end of the second swing arm 63.

The guide cover 61, the first swing arm 62, the second swing arm 63, the first guide support 64, the second guide support 65, and the like may fit together to form a guide mechanism. The guide cover 61 may be screwed to the middle frame support 203. The first guide support 64 may serve as a left guide support, and the second guide support 65 may serve as a right guide support. The left and right guide supports are fastened to the left and right bodies, respectively. The first swing arm 62 may serve as a left swing arm, and the second swing arm 63 may serve as a right swing arm. The left and right swing arms may be provided with slide rails, respectively. The slide rail corresponding to the left swing arm slides in the first chute 66. The slide rail corresponding to the right swing arm slides in the second chute 67.

The left swing arm is connected to the left guide support by a pin shaft. The right swing arm is connected to the right guide support by a pin shaft.

During unfolding and closing of the left and right bodies, under an action of an external force, the left guide support drives the left swing arm to move, and the slide rail of the left swing arm slides in the first chute 66. Likewise, under an action of an external force, the right guide support drives the right swing arm to move, and the slide rail of the right swing arm slides in the second chute 67.

The first chute 66 and the second chute 67 both serve as guide chutes. With the first swing arm 62 and the first chute 66 fitting with each other and the second swing arm 63 and the second chute 67 fitting with each other, the guide mechanism can make the left and right bodies unfold and close more smoothly.

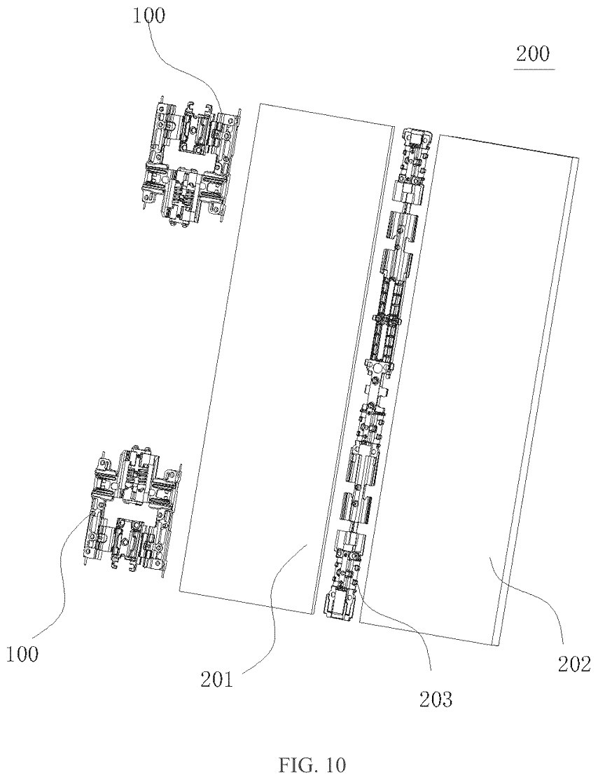

As shown in FIG. 1 and FIG. 10, there may be two guide mechanisms, with each close to an end of the middle frame support 203. With two guide mechanisms, high strength and rigidity can be ensured, and connection between the left and right bodies is also more robust.

In a process in which the hinge assembly 100 changes from the folded state to the unfolded state, the left swing arm can make the left guide support and the left body away from a center of the hinge, and the right swing arm can make the right guide support and the right body away from the center of the hinge. In this way, the left and right bodies are always wrapped around the screen during movement, avoiding the situation that the screen is not protected by the bodies when changing from the folded state to the unfolded state.

In summary, according to the hinge assembly 100 in the embodiments of this application, the first gear end 411 and the first movable piece 41 are designed as one piece, and the second gear end 421 and the second movable piece 42 are designed as one piece, reducing the number of parts. The first movable piece 41 and the second movable piece 42 directly participate in engaging, shortening the synchronization chain, reducing intermediate links and an assembly tolerance, achieving better synchronization, and improving compactness of the structure and space utilization. In addition, the first synchronizing shaft 20 needs only the first circlip 56 for fastening the first end of the first synchronizing shaft 20, because a position of the second end of the first synchronizing shaft 20 can be directly limited by the synchronizing shaft cap. Likewise, the second synchronizing shaft 30 also needs only one circlip for position limiting, reducing the number of required circlips, and providing merits such as a simple structure, easy fitting, and low costs.

The present application further provides an electronic device. The electronic device includes a flexible screen, a first part 201, a second part 202, and the hinge assembly 100 according to any one of the foregoing embodiments. The first part 201 is connected to the first movable piece 41, the second part 202 is connected to the second movable piece 42, and the flexible screen covers the first part 201, the hinge assembly 100, and the second part 202.

As shown in FIG. 1, there may be two hinge assemblies 100. The two hinge assemblies 100 may be disposed on two sides of a direction of an axis along which the electronic device is folded, respectively. In addition, the hinge assemblies 100 may be located underneath a foldable screen. It should be noted that the number of the hinge assemblies 100 is not limited to two. In some alternative embodiments, there may be a plurality of hinge assemblies 100.

It should be noted that merely a U-shaped foldable terminal is illustrated in the embodiments of the present application, and tri-fold foldable terminals and multi-layer foldable terminals may also use the hinge assembly 100 in the embodiments of this application.

The electronic device 200 in this application is not limited to a mobile phone. In some alternative embodiments, electronic device 200 may be an electronic consumer product such as a PC or a tablet.

It should be noted that all embodiments in this specification are described in a progressive manner. Each embodiment focuses on differences from other embodiments. For the part that is the same or similar between different embodiments, reference may be made between the embodiments.

Although some embodiments in the embodiments of this application have been described, persons skilled in the art can make changes and modifications to these embodiments once they learn the basic inventive concept. Therefore, the following claims are intended to be construed as to cover the embodiments and all changes and modifications falling within the scope of the embodiments of this application.

Finally, it should be noted that in this specification, relational terms such as first and second are used only to differentiate an entity from another entity, and do not necessarily require or imply that any actual relationship or sequence exists between these entities. Moreover, the term “include,” “comprise,” or any other variant thereof is intended to cover a non-exclusive inclusion, so that an article or a terminal device that includes a list of elements not only includes those elements but also includes other elements that are not expressly listed, or further includes elements inherent to such article or terminal device. In absence of more constraints, an element preceded by “includes a . . . ” does not preclude existence of other identical elements in the article or terminal device that includes the element.

The technical solutions provided in this application are described in detail above. The principle and the implementations of this application are described in this specification by using examples. In addition, a person of ordinary skill in the art can make changes to the implementations and the application scope according to the principle and the implementations of this application. Therefore, the content of this specification shall not be construed as a limitation on this application.

What is claimed is:

1. A hinge assembly, comprising:
a base provided with a first fitting portion and a second fitting portion;
a first synchronizing shaft, wherein a first end of the first synchronizing shaft is able to be movably connected to the first fitting portion;
a second synchronizing shaft, wherein a first end of the second synchronizing shaft is able to be movably connected to the second fitting portion;
a first movable piece, wherein a first end of the first movable piece is provided with a first gear sleeve, wherein an outer surface of the first gear sleeve is provided with a first gear end, and the first gear sleeve is connected to and moves synchronously with the first synchronizing shaft; and
a second movable piece, wherein a first end of the second movable piece is provided with a second gear sleeve, wherein an outer surface of the second gear sleeve is provided with a second gear end, the second gear sleeve is connected to and moves synchronously with the second synchronizing shaft, and the second gear end engages with the first gear end.

2. The hinge assembly according to claim 1, further comprising:
a first gear, wherein the first gear is able to be rotatably disposed on the base, and the first gear engages with the first gear end; and
a second gear, wherein the second gear is able to be rotatably disposed on the base, and the second gear engages with both the first gear and the second gear end.

3. The hinge assembly according to claim 1,
wherein the first gear sleeve is provided with a first mounting hole, and a second end of the first synchronizing shaft is disposed in the first mounting hole; and
wherein the second gear sleeve is provided with a second mounting hole, and a second end of the second synchronizing shaft is disposed in the second mounting hole.

4. The hinge assembly according to claim 3,
wherein the first synchronizing shaft is a cylindrical piece, a section of the first synchronizing shaft in an axial direction of the first synchronizing shaft is non-circular, and an inner wall surface of the first mounting hole presses against an outer wall surface of the first synchronizing shaft; and
wherein the second synchronizing shaft is a cylindrical piece, a section of the second synchronizing shaft in an axial direction of the second synchronizing shaft is non-circular, and an inner wall surface of the second mounting hole presses against an outer wall surface of the second synchronizing shaft.

5. The hinge assembly according to claim 1, further comprising:
a first elastic piece, wherein a first end of the first elastic piece in a telescoping direction of the first elastic piece is connected to the first fitting portion, and a second end of the first elastic piece in the telescoping direction of the first elastic piece is connected to the first gear sleeve; and
a second elastic piece, wherein a first end of the second elastic piece in a telescoping direction of the second elastic piece is connected to the second fitting portion, and a second end of the second elastic piece in the telescoping direction of the second elastic piece is connected to the second gear sleeve.

6. The hinge assembly according to claim 5,
wherein the first gear sleeve has a first fitting surface that is provided opposite the second end of the first elastic piece, wherein the first fitting surface is provided with a plurality of first protruding portions that are spaced apart in a direction in which the first synchronizing shaft rotates, and a first recessed portion is formed between two adjacent first protruding portions;
wherein the second gear sleeve has a second fitting surface that is provided opposite the second end of the second elastic piece, wherein the second fitting surface is provided with a plurality of second protruding portions that are spaced apart in a direction in which the second synchronizing shaft rotates, and a second recessed portion is formed between two adjacent second protruding portions; and
wherein the hinge assembly further comprises:
a first cam, wherein the first cam is connected to the second end of the first elastic piece, and the first cam has a third fitting surface facing the first fitting surface,
wherein the third fitting surface is provided with a first protrusion and a first recess that are spaced apart in a direction in which the first synchronizing shaft rotates, wherein: a shape of the first protrusion corresponds to a shape of the first recessed portion, a shape of the first recess corresponds to a shape of the first protruding portion, and the first cam is able to rotate around an axis of the first synchronizing shaft to adjust a preload of the first elastic piece against the first gear sleeve; and
a second cam, wherein the second cam is connected to the second end of the second elastic piece, and the second cam has a fourth fitting surface facing the second fitting surface,
wherein: the fourth fitting surface is provided with a second protrusion and a second recess that are spaced apart in a direction in which the second synchronizing shaft rotates, wherein: a shape of the second protrusion corresponds to a shape of the second recessed portion, a shape of the second recess corresponds to a shape of the second protruding portion, and the second cam is able to rotate around an axis of the second synchronizing shaft to adjust a preload of the second elastic piece against the second gear sleeve.

7. The hinge assembly according to claim 1, further comprising:
a position-limiting piece, wherein the position-limiting piece is connected to both a second end of the first synchronizing shaft and a second end of the second synchronizing shaft, and the position-limiting piece is provided with a first positioning hole and a second positioning hole, wherein the second end of the first synchronizing shaft passes through the first positioning hole, and the second end of the second synchronizing shaft passes through the second positioning hole.

8. The hinge assembly according to claim 7, wherein the second end of the first synchronizing shaft and the second end of the second synchronizing shaft are each provided with a shaft cap, and the hinge assembly further comprises:
a first circlip connected to the first end of the first synchronizing shaft; and
a second circlip connected to the first end of the second synchronizing shaft.

9. The hinge assembly according to claim 1, further comprising:
a guide cover spaced apart from the base, wherein two ends of a first surface of the guide cover are provided with a first chute and a second chute, respectively;
a first swing arm, wherein a first end of the first swing arm is slidably connected to the first chute;
a second swing arm, wherein a first end of the second swing arm is slidably connected to the second chute;
a first guide support, wherein a first end of the first guide support is movably connected to a second end of the first swing arm; and
a second guide support, wherein a first end of the second guide support is movably connected to a second end of the second swing arm.

10. An electronic device, comprising a flexible screen; a first part; a second part; and the hinge assembly,
wherein the hinge assembly comprises:
a base provided with a first fitting portion and a second fitting portion;
a first synchronizing shaft, wherein a first end of the first synchronizing shaft is able to be movably connected to the first fitting portion;
a second synchronizing shaft, wherein a first end of the second synchronizing shaft is able to be movably connected to the second fitting portion;
a first movable piece, wherein a first end of the first movable piece is provided with a first gear sleeve, wherein an outer surface of the first gear sleeve is provided with a first gear end, and the first gear sleeve is connected to and moves synchronously with the first synchronizing shaft; and
a second movable piece, wherein a first end of the second movable piece is provided with a second gear sleeve, wherein an outer surface of the second gear sleeve is provided with a second gear end, the second gear sleeve is connected to and moves synchronously with the second synchronizing shaft, and the second gear end engages with the first gear end,
wherein: the first part is connected to the first movable piece, the second part is connected to the second movable piece, and the flexible screen covers the first part, the hinge assembly, and the second part.

11. The electronic device according to claim 10, wherein the hinge assembly further comprises:
a first gear, wherein the first gear is able to be rotatably disposed on the base, and the first gear engages with the first gear end; and
a second gear, wherein the second gear is able to be rotatably disposed on the base, and the second gear engages with both the first gear and the second gear end.

12. The electronic device according to claim 10,
wherein the first gear sleeve is provided with a first mounting hole, and a second end of the first synchronizing shaft is disposed in the first mounting hole; and
wherein the second gear sleeve is provided with a second mounting hole, and a second end of the second synchronizing shaft is disposed in the second mounting hole.

13. The electronic device according to claim 12,
wherein the first synchronizing shaft is a cylindrical piece, a section of the first synchronizing shaft in an axial direction of the first synchronizing shaft is non-circular, and an inner wall surface of the first mounting hole presses against an outer wall surface of the first synchronizing shaft; and
wherein the second synchronizing shaft is a cylindrical piece, a section of the second synchronizing shaft in an axial direction of the second synchronizing shaft is non-circular, and an inner wall surface of the second mounting hole presses against an outer wall surface of the second synchronizing shaft.

14. The electronic device according to claim 10, wherein the hinge assembly further comprises:
a first elastic piece, wherein a first end of the first elastic piece in a telescoping direction of the first elastic piece is connected to the first fitting portion, and a second end of the first elastic piece in the telescoping direction of the first elastic piece is connected to the first gear sleeve; and
a second elastic piece, wherein a first end of the second elastic piece in a telescoping direction of the second elastic piece is connected to the second fitting portion, and a second end of the second elastic piece in the telescoping direction of the second elastic piece is connected to the second gear sleeve.

15. The electronic device according to claim 14,
wherein the first gear sleeve has a first fitting surface that is provided opposite the second end of the first elastic piece, wherein the first fitting surface is provided with a plurality of first protruding portions that are spaced apart in a direction in which the first synchronizing shaft rotates, and a first recessed portion is formed between two adjacent first protruding portions;
wherein the second gear sleeve has a second fitting surface that is provided opposite the second end of the second elastic piece, wherein the second fitting surface is provided with a plurality of second protruding portions that are spaced apart in a direction in which the second synchronizing shaft rotates, and a second recessed portion is formed between two adjacent second protruding portions; and
wherein the hinge assembly further comprises:
a first cam, wherein the first cam is connected to the second end of the first elastic piece, and the first cam has a third fitting surface facing the first fitting surface,
wherein the third fitting surface is provided with a first protrusion and a first recess that are spaced apart in a direction in which the first synchronizing shaft rotates, wherein: a shape of the first protrusion corresponds to a shape of the first recessed portion, a shape of the first recess corresponds to a shape of the first protruding portion, and the first cam is able to rotate around an axis of the first synchronizing shaft to adjust a preload of the first elastic piece against the first gear sleeve; and
a second cam, wherein the second cam is connected to the second end of the second elastic piece, and the second cam has a fourth fitting surface facing the second fitting surface,
wherein: the fourth fitting surface is provided with a second protrusion and a second recess that are spaced apart in a direction in which the second synchronizing shaft rotates, wherein: a shape of the second protrusion corresponds to a shape of the second recessed portion, a shape of the second recess corresponds to a shape of the second protruding portion, and the second cam is able to rotate around an axis of the second synchronizing shaft to adjust a preload of the second elastic piece against the second gear sleeve.

16. The electronic device according to claim 10, wherein the hinge assembly further comprises:
a position-limiting piece, wherein the position-limiting piece is connected to both a second end of the first synchronizing shaft and a second end of the second synchronizing shaft, and the position-limiting piece is provided with a first positioning hole and a second positioning hole, wherein the second end of the first synchronizing shaft passes through the first positioning hole, and the second end of the second synchronizing shaft passes through the second positioning hole.

17. The electronic device according to claim 16, wherein the second end of the first synchronizing shaft and the second end of the second synchronizing shaft are each provided with a shaft cap, and the hinge assembly further comprises:
a first circlip connected to the first end of the first synchronizing shaft; and
a second circlip connected to the first end of the second synchronizing shaft.

18. The electronic device according to claim 10, the hinge assembly further comprises:
a guide cover spaced apart from the base, wherein two ends of a first surface of the guide cover are provided with a first chute and a second chute, respectively;
a first swing arm, wherein a first end of the first swing arm is slidably connected to the first chute;
a second swing arm, wherein a first end of the second swing arm is slidably connected to the second chute;
a first guide support, wherein a first end of the first guide support is movably connected to a second end of the first swing arm; and
a second guide support, wherein a first end of the second guide support is movably connected to a second end of the second swing arm.
